(19) United States
(12) Patent Application Publication
(10) Pub. No.: US 2008/0142786 A1
(43) Pub. Date: Jun. 19, 2008

(54) INSULATED GATE FOR GROUP III-V DEVICES

(76) Inventors: Suman Datta, Beaverton, OR (US); Jack T. Kavalieros, Portland, OR (US); Gilbert Dewey, Hillsboro, OR (US); Marko Radosavljevic, Beaverton, OR (US)

Correspondence Address: INTEL CORPORATION;c/o INTELLEVATE, LLC, P.O. BOX 52050, MINNEAPOLIS, MN, 55402, US

(21) Appl. No.: 11/610,415

(22) Filed: Dec. 13, 2006

(51) Int. Cl. H01L 29/12

(52) U.S. Cl. 257/24; 257/E29.069

(57) ABSTRACT

A group III-V material device may have a capping layer on a barrier region, which may provide a high quality interface for a high-k gate dielectric. This may improve the performance of the device by reducing gate leakage and preserve the high-mobility properties of the quantum well channel region of the device.

### BACKGROUND

### BACKGROUND OF THE INVENTION

Most integrated circuits today are based on silicon, a Group IV element of the Periodic Table. Compounds of Group III-V elements such as gallium arsenide (GaAs), indium antimonide (InSb), indium phosphide (InP), and indium gallium arsenide (InGaAs) are known to have far superior semiconductor properties than silicon, including higher electron mobility and saturation velocity. These materials may thus provide superior device performance.

Silicon easily oxidizes to form an almost perfect electrical interface. This makes possible the near total confinement of charge with a few atomic layers of silicon dioxide. In contrast, oxides of Group III-V materials may be of poor quality. Quantum well transistors using elements from columns III through V of the periodic table may be prone high gate leakage and parasitic series resistance.

### BRIEF DESCRIPTION OF THE DRAWINGS

FIG. 1 is a cross sectional side view that illustrates a group III-V material quantum well transistor device.

FIG. 2 is a cross sectional side view that illustrates the substrate.

FIG. 3 is a cross sectional side view that illustrates a buffer region that is formed on the substrate.

FIG. 4 is a cross sectional side view that illustrates a bottom barrier region on the buffer region.

FIG. 5 is a cross sectional side view that illustrates a quantum well channel region on the bottom barrier region.

FIG. 6 is a cross sectional side view that illustrates an upper barrier region on the quantum well channel region.

FIG. 7 is a cross sectional side view that illustrates a capping region on the upper barrier region.

FIG. 8 is a cross sectional side view that illustrates a high-k layer on the capping region.

FIG. 9 is a cross sectional side view that illustrates another embodiment with a spacer region and a delta-doped region.

FIG. 10 illustrates a system in accordance with one embodiment of the present invention.

### DETAILED DESCRIPTION

In various embodiments, an apparatus and method relating to the formation of a group III-V material semiconductor device with a high-quality gate dielectric are described. In the following description, various embodiments will be described. However, one skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

Various operations will be described as multiple discrete operations in turn, in a manner that is most helpful in understanding the invention. However, the order of description should not be construed as to imply that these operations are necessarily order dependent. In particular, these operations need not be performed in the order of presentation. Operations described may be performed in a different order, in series or in parallel, than the described embodiment. Various additional operations may be performed and/or described operations may be omitted in additional embodiments.

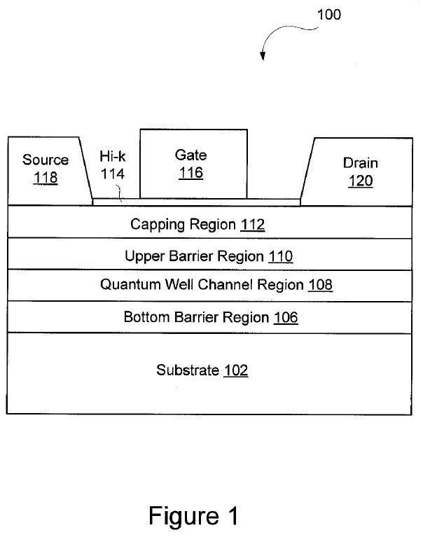

FIG. 1 is a cross sectional side view that illustrates a group III-V material quantum well transistor device 100 with a high dielectric value (“high-k”) gate dielectric layer 114, according to one embodiment of the present invention. As used herein “high dielectric value” refers to dielectrics having dielectric constants of 10 or greater. The high-k gate dielectric layer 114 is on a capping region 112 that to help reduce gate leakage while providing a high quality interface with the high-k gate dielectric 114 with acceptable surface state density and helps preserve the high-mobility properties of the quantum well region 108 free from an unacceptable level of surface scattering effects. In an embodiment, the high-k gate dielectric 114 has a surface state density of less than about 5×10¹¹ per cm².

In the illustrated embodiment, the device 100 includes a substrate 102, which may include one or more material(s) and layer(s). The substrate 102 may be any material or materials on which the device 100 may be made. There is a bottom barrier region 106 on the substrate 102, a quantum well channel region 108 on the bottom barrier region 106, and an upper barrier region 110 on the quantum well channel region 108. Thus, the quantum well region 108 is sandwiched between the upper and lower barrier regions 110 and 106. The upper barrier region 110 may be an electron supplying layer whose thickness will determine the threshold voltage of the transistor, along with the workfunction of the metal forming the gate electrode 116, in some embodiments.

There is a capping region 112 on the upper barrier region 110. The capping region 112 provides a high-quality interface for a high-k dielectric layer 114 on the capping region 112. Without the capping region 112, the device 100 may have a low quality interface that adversely affects device 100 performance. Alternatively, if the device 100 did not have the capping region 112, the device 100 may lack a high-k gate dielectric 114 and may thus have high gate leakage, and limited Iₒₙ/I_{off} ratio.

On the high-k gate dielectric layer 114 is a gate electrode 116, the material of which may be chosen based on a desired work function. The device 100 also has doped source and drain regions 118 and 120. As illustrated, the device 100 is a recessed gate 116 device 100, although in other embodiments it may be a different type of device 100 that lacks a recessed gate 116. There may be gate, source and drain contacts (not shown) that make electrical connections to the gate 116, source 118, and drain 120.

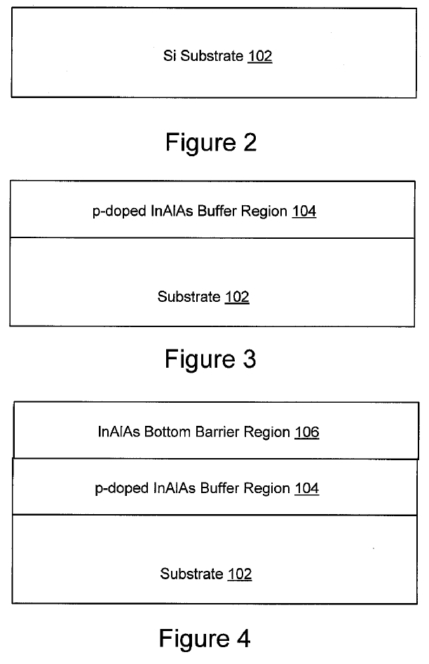

FIGS. 2 through 9 are cross sectional side views that illustrate how the device 100 may be made, and provide additional details about embodiments of the invention.

FIG. 2 is a cross sectional side view that illustrates the substrate 102, according to one embodiment of the invention. The substrate 102 may comprise high-resistivity p-type or n-type vicinal silicon material having regular arrays of double-stepped (100) terraces across the substrate surface. A vicinal surface may be prepared by offcutting the substrate 102 from an ingot. In a particular embodiment, the (100) substrate surface is offcut at an angle between 2 and 12 degrees towards the [110] direction. A vicinal surface is a higher order crystal plane of the silicon substrate 102, such as, but not limited to the (211), (511), (013), (711) planes. A vicinal substrate surface having double-stepped terraces is capable of suppressing anti-phase domains (APD) in a group III-V buffer region that may be formed on the substrate 102. An APD is created when a first polar crystal domain of a layer having group III atoms attached to the nonpolar silicon substrate 102 surface meets a second polar crystal domain of a layer having group V atoms attached to the silicon substrate 102. A crystal discontinuity may form in the layer at the border between these first and second domains providing recombination-generation centers that may be detrimental to the operation of a semiconductor device. The term “polar” refers to the partially ionic bonding character between the constituents of an III-V compound semiconductor. The high resistivity may be achieved by a low dopant concentration, lower than about 10¹⁶ carriers/cm³. In other embodiments, other materials than Si could be used. For example, the substrate 102 could comprise germanium, germanium on silicon, could be a silicon-on-insulator substrate 102, could comprise gallium arsenide (GaAs), a semi-insulating layer, or could comprise another material.

FIG. 3 is a cross sectional side view that illustrates a buffer region 104 that is formed on the substrate 102 in one embodiment. While buffer region 104 was not shown in FIG. 1, it may be present in various embodiments. The buffer region 104 may function to accommodate for a lattice mismatch between the substrate 102 and regions above the buffer region 104 and to confine lattice dislocations and defects. In the illustrated embodiment, the buffer region 104 comprises p-doped InAlAs. In an embodiment, the buffer region 104 may have about 52% In to about 48% Al. In other embodiments it may comprise other materials such as InP. There may be a nucleation region between the buffer region 104 and the substrate 102 in other embodiments, and/or additional buffer region(s). The buffer region 104 and nucleation region, if present, may be formed by any suitable process, such as molecular beam epitaxy (MBE), metal-organic chemical vapor deposition (MOCVD), atomic layer epitaxy (ALE), chemical beam epitaxy (CBE), or other methods may be used. The buffer region 104 may be p-doped to create enough bandbending to deplete the regions on top of the buffer region 104 when the device 100 is in operation. In other embodiments, the buffer region 104 may be undoped.

FIG. 4 is a cross sectional side view that illustrates a bottom barrier region 106 on the buffer region 104, according to one embodiment. The bottom barrier region 106 comprises InAlAs in the illustrated embodiment, although in other embodiments it may comprise other materials such as InAlSb or InP. The bottom barrier region 106 may comprise a material with a higher band gap than the material of which the quantum well channel region 108 is comprised. Any suitable method, such as those listed as possible to form the buffer region 104, above, may be used to form the bottom barrier region 106. In some embodiments, the bottom barrier region 106 may have a thickness between about one micron and three microns, although it may have different thicknesses in other embodiments.

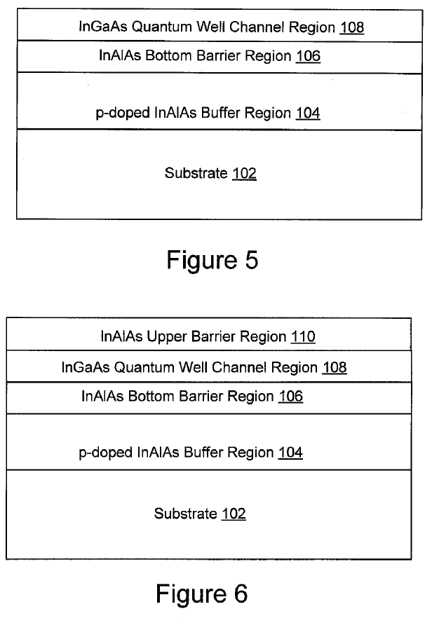

FIG. 5 is a cross sectional side view that illustrates a quantum well channel region 108 on the bottom barrier region 106, according to one embodiment. This quantum well channel region 108 comprises InGaAs in the illustrated embodiment, although in other embodiments it may comprise other materials such as InSb or InAs. In an embodiment where the quantum well channel region 108 comprises InGaAs, there may be a ratio of In to Ga of about 53 to 47, which could give the quantum well channel region 108 a rough lattice match to surrounding regions. In another embodiment, the ratio may be 80 to 20, which could provide a strain to the region 108. Other ratios, such as rations between 53:47 and 80:20 could be used. Any suitable method, such as those listed as possible to form the buffer region 104, above, may be used to form the quantum well channel region 108. In some embodiments, the quantum well channel region 108 may have a thickness between about 3 nanometers and twenty nanometers, although it may have different thicknesses in other embodiments.

FIG. 6 is a cross sectional side view that illustrates an upper barrier region 110 on the quantum well channel region 108, according to one embodiment. The upper barrier region 110 comprises InAlAs in the illustrated embodiment, although in other embodiments it may comprise other materials. In an embodiment where the upper barrier region 110 comprises InAlAs, there may be a ratio of In to Al of about 52 to 48. The upper barrier region 110 may comprise a material with a higher band gap than the material of which the quantum well channel region 108 is comprised. In an embodiment, the upper barrier region 110 comprises the same material as the bottom barrier region 106. In an embodiment, the upper barrier region 110 consists of substantially the same material as the bottom barrier region 106. In other embodiments, the upper and bottom barrier regions 106, 110 may comprise different materials. Any suitable method, such as those listed as possible to form the buffer region 104, above, may be used to form the upper barrier region 110. In some embodiments, the upper barrier region 110 may have a thickness between about 3 nanometers and 50 nanometers, although it may have different thicknesses in other embodiments, and this thickness may be chosen based on the targeted threshold voltage for the device 100.

Thus, the quantum well channel region 108 is sandwiched between upper and bottom barrier regions 106, 110. The upper barrier region 110 may be an electron supplying region whose thickness may determine the threshold voltage of the transistor device 100, along with the workfunction of the metal gate 116.

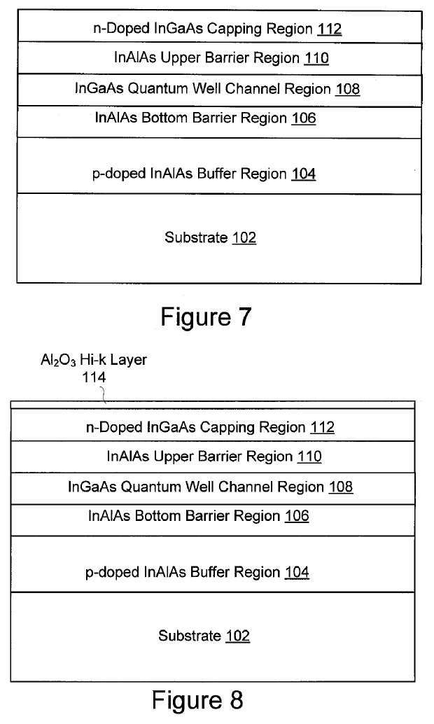

FIG. 7 is a cross sectional side view that illustrates a capping region 112 on the upper barrier region 110, according to one embodiment. The capping region 112 illustrated in FIG. 7 comprises an n-doped InGaAs material, although other materials may be used in other embodiments, and the capping region 112 may be undoped rather than n-doped. In an embodiment where the capping region 112 comprises InGaAs, there may be a ratio of In to Ga of about 53 to 47. In an embodiment, the capping region 112 has a thickness less than about 30 nanometers. The capping region 112 may be epitaxially grown in an embodiment, although other methods may be used in other embodiments. In some embodiments, the capping region 112 may have a thickness between about 0.5 nanometers and 5 nanometers, although it may have different thicknesses in other embodiments.

FIG. 8 is a cross sectional side view that illustrates a high-k layer 114 on the capping region 112, according to one embodiment. The high-k layer 114 illustrated in FIG. 8 comprises Al₂O₃, although other materials such as La₂O₃, HfO₂, ZrO₂, or ternary complexes such as LaAlₓO_{y}, HfₓZr_{y}O_{z} may be used in other embodiments. The Al₂O₃ may be deposited using trimethylaluminum (TMA) and water precursors with and ALD process in one embodiment, although other methods to form it may be used. In some embodiments, the high-k layer 114 may have a thickness between about 0.7 nanometers and 5 nanometers, although it may have different thicknesses in other embodiments. The high-k layer 114 may reduce gate leakage to provide for better device 100 performance. The capping region 112, in turn, may provide a high-quality interface for the high-k layer 114 with a low density of surface states, which might not be present if the high-k layer 114 were directly on the upper barrier region 112. The capping region 112 may lower the density of surface states by about one order of magnitude in some embodiments, such as lowering the density from 1×10¹³/cm² to 1×10¹²/cm², as estimated from CV dispersion characteristics.

Further processes may be performed to make the device 100 shown in FIG. 1. The gate 116, which may be a metal gate 116, and the source and drain regions 118, 120 are formed. In the illustrated embodiment, the gate 116 is a recessed gates of a transistor, so portions of a source/drain layer are removed to recess the gate 116, leaving the source and drain regions 118, 120. The recessed source, drain, and gate are formed by e-beam evaporation of metal and lift-off or float-off in an embodiment. In other embodiments, other types of transistors or other devices 100 may be formed, which may lack the recesses in the source/drain layer.

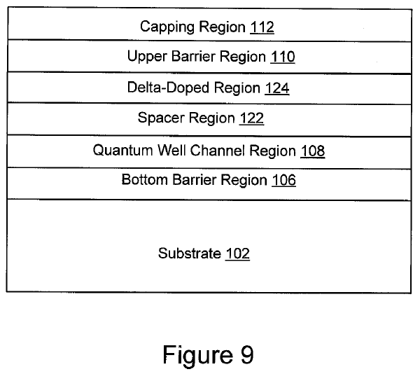

FIG. 9 is a cross sectional side view that illustrates another embodiment with a spacer region 122 and a delta-doped region 124. The stage of device 100 fabrication shown in FIG. 9 is similar to the fabrication stage of the embodiment shown in FIG. 7. In the embodiment shown in FIG. 9, there is a spacer region 122 on the quantum well channel region 108, a delta-doped region 124 on the spacer region 122, and the upper barrier region 110 is on the delta-doped region. The spacer region 122 may comprise the same material as the upper barrier region 110 in an embodiment. In an embodiment, the spacer region 122 may consist substantially of the same material as the upper barrier region 110. The delta-doped region 124 may comprise the same material as the spacer region 122 and/or the upper barrier region 110, with the addition of a dopant or dopants. The dopant used in the delta-doped region 124 may be Te, Si, Be, or another dopant. There may be a dopant density in the delta-doped region 124 of between about 1×10¹¹/cm² to about 8×10¹²/cm² in some embodiments, although different dopant densities may be used. The density of dopants may be chosen based by the device 100 design and targeted threshold voltage of the device. In an embodiment, the spacer region 122, delta-doped region 124, and upper barrier region 110 may be formed by MBE (molecular beam epitaxy) in a continuous growth process, with the addition of a flow of the dopants to the chamber when forming the delta-doped region 124. In some embodiments, the spacer region 122 may have a thickness between about 1 nanometer and about 5 nanometers, although it may have different thicknesses in other embodiments.

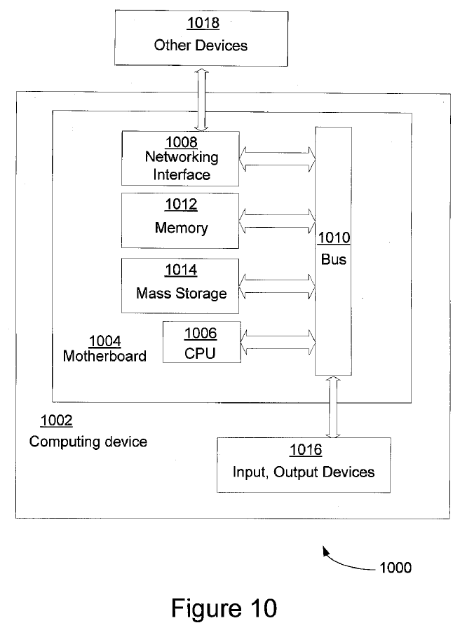

FIG. 10 illustrates a system 1000 in accordance with one embodiment of the present invention. One or more devices 100 may be included in the system 1000 of FIG. 10. As illustrated, for the embodiment, system 1000 includes a computing device 1002 for processing data. Computing device 1002 may include a motherboard 1004. Coupled to or part of the motherboard 1004 may be in particular a processor 1006, and a networking interface 1008 coupled to a bus 1010. A chipset may form part or all of the bus 1010.

Depending on the applications, system 1000 may include other components, including but are not limited to volatile and non-volatile memory 1012, a graphics processor (integrated with the motherboard 1004 or connected to the motherboard as a separate removable component such as an AGP or PCI-E graphics processor), a digital signal processor, a crypto processor, mass storage 1014 (such as hard disk, compact disk (CD), digital versatile disk (DVD) and so forth), input and/or output devices 1016, and so forth.

In various embodiments, system 1000 may be a personal digital assistant (PDA), a mobile phone, a tablet computing device, a laptop computing device, a desktop computing device, a set-top box, an entertainment control unit, a digital camera, a digital video recorder, a CD player, a DVD player, or other digital device of the like.

The foregoing description of the embodiments of the invention has been presented for the purposes of illustration and description. It is not intended to be exhaustive or to limit the invention to the precise forms disclosed. This description and the claims following include terms, such as left, right, top, bottom, over, under, upper, lower, first, second, etc. that are used for descriptive purposes only and are not to be construed as limiting. For example, terms designating relative vertical position refer to a situation where a device side (or active surface) of a substrate or integrated circuit is the “top” surface of that substrate; the substrate may actually be in any orientation so that a “top” side of a substrate may be lower than the “bottom” side in a standard terrestrial frame of reference and still fall within the meaning of the term “top.” The term “on” as used herein (including in the claims) does not indicate that a first layer “on” a second layer is directly on and in immediate contact with the second layer unless such is specifically stated; there may be a third layer or other structure between the first layer and the second layer on the first layer. The embodiments of a device or article described herein can be manufactured, used, or shipped in a number of positions and orientations. Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

1. A group III-V quantum well transistor comprising:
a lower barrier region comprising InAIAs;
a quantum well channel region comprising InGaAs on the lower barrier region;
an upper barrier region comprising InAIAs on the quantum well channel region;
a capping region comprising InGaAs disposed on a top surface of the upper barrier region; and
a high-k gate dielectric layer on the capping region, wherein the high-k gate dielectric layer has a dielectric constant of at least about 10.

2. The transistor of claim 1, further comprising a gate electrode on the high-k gate dielectric layer.

3. The transistor of claim 2, further comprising a source region on a first side of the gate electrode and a drain region on a second side of the gate electrode opposite the first side.

4. The transistor of claim 1, wherein the gate electrode comprises a metal.

5. The transistor of claim 1, further comprising a substrate comprising InAIAs under the lower barrier region.

6. The transistor of claim 1, further comprising a delta-doped region between the quantum well channel region and the capping region.

7. A semiconductor device comprising:
a lower barrier region;
a quantum well channel region comprising a group III-V material on the lower barrier region;
an upper barrier region on the quantum well channel region;
a capping region comprising a group III-V material disposed on a top surface of the upper barrier region; and
a high-k gate dielectric layer on the capping region, wherein the high-k gate dielectric layer has a dielectric constant of at least about 10.

8. The device of claim 7, wherein the capping region has a thickness less than about 30 nm.

9. The device of claim 7, wherein the quantum well channel region comprises InGaAs.

10. The device of claim 9, wherein the upper barrier region and the lower barrier region each comprise InAIAs.

11. The device of claim 10, wherein the capping region comprises InGaAs.

12. The device of claim 11, wherein the high-k gate dielectric layer comprises AI2O3.

13. The device of claim 12, further comprising a gate electrode on the high-k gate dielectric layer, the gate electrode comprising a metal.

14. The device of claim 7, further comprising spacer region on the quantum well channel region and a delta-doped region that is on the spacer region, wherein the upper barrier region is on the delta-doped region.

15. A transistor comprising:
a lower barrier region;
a quantum well channel region comprising a first group III-V material on the lower barrier region;
an upper barrier region on the quantum well channel region;
a capping region comprising the first group III-V material disposed on a top surface of the upper barrier region; and
a high-k gate dielectric layer on the capping region, wherein the high-k gate dielectric layer has a dielectric constant of at least about 10.

16. The transistor of claim 15, wherein the high-k dielectric layer is directly in contact with the capping region.

17. The transistor of claim 15, wherein the capping region comprises InGaAs.

18. The transistor of claim 17, wherein the upper barrier region and the lower barrier region each comprise InAIAs.

19. The transistor of claim 17, wherein the capping region is n-doped.

20. The transistor of claim 15, further comprising a substrate that comprises p-doped InAIAs under the barrier region.
